(19) United States
(12) Patent Application Publication
(10) Pub. No.: US 2025/0081347 A1
(43) Pub. Date: Mar. 6, 2025

(54) ELECTRICAL CONNECTION DEVICE

(71) Applicant: Industrial Technology Research Institute, Hsinchu (TW)

(72) Inventors: Chung-Wei Wang, Hsinchu City (TW); Chen-Tsai Yang, Taoyuan City (TW); Shu-Wei Kuo, Hsinchu County (TW); Min-Hsiung Liang, Hsinchu County (TW); Bor-Chuan Chuang, Tainan County (TW)

(73) Assignee: Industrial Technology Research Institute, Hsinchu (TW)

(21) Appl. No.: 18/820,278

(22) Filed: Aug. 30, 2024

Related U.S. Application Data
(60) Provisional application No. 63/535,558, filed on Aug. 30, 2023.

(30) Foreign Application Priority Data
Jul. 29, 2024 (TW) 113128074

(51) Int. Cl. H05K 1/14; H05K 1/11

(52) U.S. Cl. CPC H05K 1/141; H05K 1/117; H05K 2201/045; H05K 2201/08

(57) ABSTRACT

An electrical connection device includes a mother board and a daughter board. The mother board includes a first board body with at least one cavity and a first electrical contact printed on the first board body. The daughter board includes a second board body and a second electrical contact printed on the second board body. At least one of the daughter board and the mother board includes at least one contour feature integrally formed with at least one of the first board body and the second board body. When the second board body is inserted into the at least one cavity of the first board body, the second electrical contact is electrically connected to the first electrical contact, and the daughter board is positioned in the mother board through the at least one contour feature.

### CROSS-REFERENCE TO RELATED APPLICATION

This application claims the priority benefit of U.S. provisional application Ser. No. 63/535,558, filed on Aug. 30, 2023, and Taiwan application serial no. 113128074, filed on Jul. 29, 2024. The entirety of the above-mentioned patent application is hereby incorporated by reference herein and made a part of this specification.

### TECHNICAL FIELD

The disclosure relates to an electrical connection device, and to an electrical connection device that transmits an electrical signal.

### BACKGROUND

In order to cope with a trend of thinner and lighter electronic products, assembly mechanisms, parts, and electrical connectors of the product are required to be miniaturized, making assembly difficult and easily causing issues of poor reliability such as electrical properties and fixation. In the existing technology, when integrally formed modules and components are to be integrated and/or connected to other components, due to a large size and weight of a pin connector, cracks are likely to occur in soft and hard interfaces during a cable plugging and unplugging process, causing failure of signal connection. Furthermore, after thermoforming of the integrally formed modules and the components, a line may be offset due to deformation of a pitch of a signal wire after formation, making it difficult to align signal connection pins between different components. Therefore, how to effectively reduce costs and improve assembly efficiency is an important consideration for the development of the integration technology, and is also one of the important topics for relevant people of ordinary skills in the art.

### SUMMARY

An embodiment of the disclosure provides an electrical connection device, which may effectively reduce costs and improve assembly efficiency, and may have better reliability.

An electrical connection device in the embodiment of the disclosure includes a mother board and a daughter board. The mother board includes a first board body with at least one cavity and a first electrical contact printed on the first board body. The daughter board includes a second board body and a second electrical contact printed on the second board body. At least one of the daughter board and the mother board includes at least one contour feature. The at least one contour feature is integrally formed with at least one of the first board body and the second board body. When the second board body is inserted into the at least one cavity of the first board body, the second electrical contact is electrically connected to the first electrical contact, and the daughter board is positioned in the mother board through the at least one contour feature.

Based on the above, in the design of the electrical connection device in the embodiment of the disclosure, at least one of the daughter board and the mother board includes the at least one contour feature, and the at least one contour feature is integrally formed with at least one of the first board body and the second board body, which may reduce the material usage and the process steps. Therefore, when the second board body is inserted into the at least one cavity of the first board body, the second electrical contact is electrically connected to the first electrical contact, and the daughter board is positioned in the mother board through the at least one contour feature, which means that the positioning and line connection of the daughter board and the mother board may be completed at the same time, so that the electrical connection device in the disclosure may not only save costs and improve assembly efficiency, but also have better reliability

In order for the disclosure to be more comprehensible, embodiments accompanied with drawings are described in detail below.

### BRIEF DESCRIPTION OF THE DRAWINGS

FIG. 1A is a schematic three-dimensional view of an electrical connection device according to an embodiment of the disclosure.

FIG. 1B is a schematic cross-sectional view taken along a line I-I in FIG. 1A.

FIGS. 2A to 2G are side views of contour features of various shapes.

FIGS. 3A to 3G are top views corresponding to the contour features in FIGS. 2A to 2G respectively.

FIGS. 4A to 4F are schematic views of contour features with different numbers and arrangements.

FIG. 5 is a schematic cross-sectional view of an electrical connection device according to another embodiment of the disclosure.

FIG. 6 is a schematic exploded perspective view of an electrical connection device according to another embodiment of the disclosure.

FIG. 7A is a schematic cross-sectional view of an electrical connection device according to another embodiment of the disclosure.

FIG. 7B is a schematic top perspective view of the electrical connection device in FIG. 7A.

FIG. 8A is a schematic top perspective view of an electrical connection device according to another embodiment of the disclosure.

FIG. 8B is a schematic cross-sectional view of the electrical connection device in FIG. 8A.

FIG. 9A is a schematic top perspective view of an electrical connection device according to another embodiment of the disclosure.

FIG. 9B is a schematic cross-sectional view of the electrical connection device in FIG. 9A.

FIG. 10 is a schematic cross-sectional view of an electrical connection device according to another embodiment of the disclosure.

### DETAILED DESCRIPTION OF DISCLOSED EMBODIMENTS

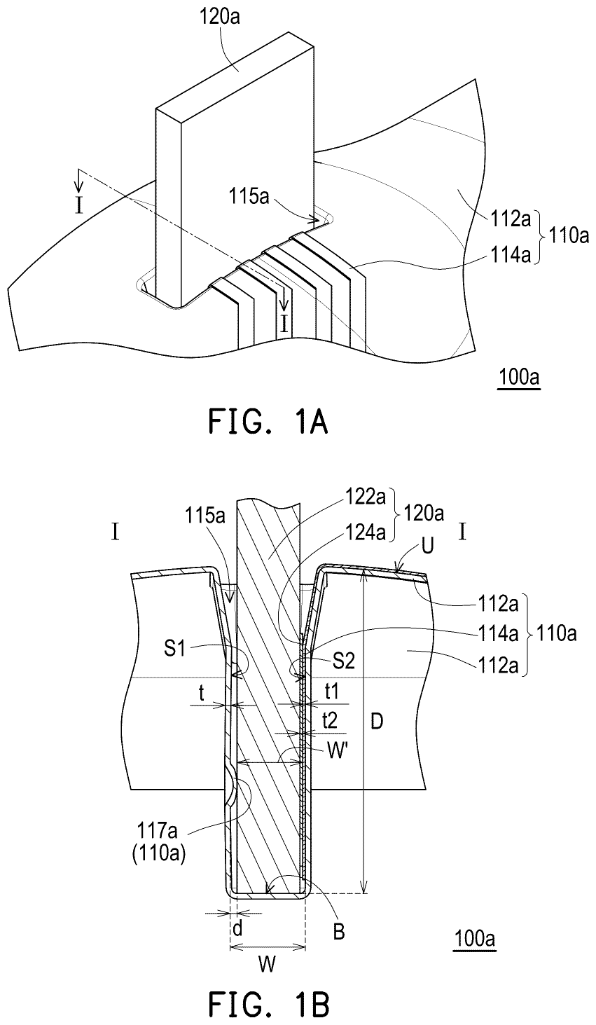

FIG. 1A is a schematic three-dimensional view of an electrical connection device according to an embodiment of the disclosure. FIG. 1B is a schematic cross-sectional view taken along a line I-I in FIG. 1A. Referring to both FIGS. 1A and 1B, in this embodiment, an electrical connection device 100a includes a mother board 110a and a daughter board 120a. The mother board 110a includes a first board body 112a with at least one cavity (a cavity 115a is schematically shown) and a first electrical contact 114a printed on the first board body 112a. The daughter board 120a includes a second board body 122a and a second electrical contact 124a printed on the second board body 122a. At least one of the daughter board 120a and the mother board 110a includes at least one contour feature, and the at least one contour feature is integrally formed with at least one of the first board body 112a and the second board body 122a. Here, the mother board 110a includes the at least one contour feature (a contour feature 117a is schematically shown), and the contour feature 117a is embodied as a bump structure. However, the disclosure is not limited thereto. When the second board body 122a is inserted into the cavity 115a of the first board body 112a, the second electrical contact 124a is electrically connected to the first electrical contact 114a, and the daughter board 120a is positioned in the mother board 110a through the contour feature 117a, which means that the positioning and line connection of the daughter board 120a and the mother board 110a may be completed at the same time.

In detail, the electrical connection device 100a in this embodiment may be used in various electronic products, which may, for example, be widely used in internal connections of electronic products in fields such as automotive electronics, consumer electronics, white goods, medical electronics, and information and communication technology (ICT). In an embodiment, the mother board 110a may be, for example, a center console or a control panel of a home appliance, and the daughter board 120a may be, for example, a USB or remote control device. However, the disclosure is not limited thereto. The cavity 115a of the mother board 110a has an upper surface U and a bottom surface B opposite to each other, and a first inner side surface S1 and a second inner side surface S2 connected to the upper surface U and the bottom surface B and opposite to each other. The bump structure 117a is located on the first inner side surface S1, and the first electrical contact 114a extends from the upper surface U and is disposed on the second inner side surface S2. That is to say, the bump structure 117a and the first electrical contact 114a are located on inner side surfaces on different sides, but the disclosure is not limited thereto.

More specifically, a protruding height of the bump structure 117a in this embodiment relative to the first inner side surface S1 is d, while a width of the cavity 115a is W, and then 0<d<(W/2). That is to say, a height d of the bump structure 117a is required to be less than ½ a width W of the cavity 115a, which may provide appropriate pressure to be applied to the daughter board 120a, so that the second electrical contact 124a on the daughter board 120a may be reliably in contact with the first electrical contact 114a on the mother board 110a, thereby enabling the electrical connection device 100a in this embodiment to have better electrical reliability. In an embodiment, the width W of the cavity 115a is, for example, between 0.1 millimeters (mm) and 10 mm. In other words, the contour feature (i.e., the bump structure 117a) located in the cavity 115a may provide appropriate lateral force (i.e., component adhesion force), which may avoid issues of poor flatness of electrical contacts and unstable signal connections.

Furthermore, an orthographic projection area of the bump structure 117a on the second inner side surface S2 is at least 20% greater than a contact area between the second electrical contact 124a and the first electrical contact 114a, which may ensure electrical signal transmission. In an embodiment, a thickness t1 of the first electrical contact 114a and a thickness t2 of the second electrical contact 124a range, for example, from 0.002 mm to 0.5 mm respectively. In an embodiment, a thickness t of the cavity 115a is, for example, 0.1 mm to 3 mm. In an embodiment, a depth D of the cavity 115a (i.e., a distance from the upper surface U to the bottom surface B) is, for example, greater than 3 mm. In an embodiment, a width W′ of the daughter board 120a is, for example, between 0.1 mm and 10 mm.

In addition, different lengths, widths, depths, material thicknesses of the cavity 115a, the height d, positions, shapes, numbers of the bump structure 117a, and different thicknesses of the daughter board 120a all affect the lateral force (i.e. the component adhesion force), and affect different stress distribution generated by the first inner side surface S1 and the second inner side surface S2 of the cavity 115a. Generally speaking, the height d of the bump structure 117a is proportional to lateral pressure. In a simulation experiment, the bump structure 117a is located at a center of the first inner side surface S1 of the cavity 115a. A material of the first board body 112a is, for example, polycarbonate (PC), and a Young's modulus thereof is E=1.5 GPa. A maximum stress value applied by the bump structure 117a on the daughter board 120a is, for example, less than a material yield strength (e.g., 30 MPa) of the mother board 110a, and average contact force between the second electrical contact 124a and the first electrical contact 114a is, for example, greater than 100 gram force (gf).

In addition, in an embodiment, a material of the first electrical contact 114a and a material of the second electrical contact 124a are, for example, metal materials, such as copper. In an embodiment, the first board body 112a and the second board body 122a may be, for example, a flexible printed circuit board (FPC) or a flexible flat cable (FFC). In an embodiment, a material of the first board body 112a and a material of the second board body 122a may be, for example, polycarbonate (PC), polymethyl methacrylate (PMMA), polyethylene terephthalate (PET), cycloolefin polymer (COP), polyolefin (PO), cast polypropylene films (CPP), oriented polypropylene films (OPP), silicone films, thermoplastic polyurethane (TPU), polyurethane or acrylonitrile-butadiene-styrene copolymers (ABS), but the disclosure is not limited thereto. In an embodiment, the material of the first board body 112a and the material of the second board body 122a may be the same or different.

In terms of a manufacturing process, the first electrical contact 114a is printed on a substrate of a mother board. Printed electronics is to manufacture a patterned material on a thin film layer using the printing technology for electronic or electrical purposes. A printing technology process includes, but is not limited to, inkjet printing, screen printing, gravure printing, relief printing, or aerosol jet printing. Then, the contour feature (i.e., the bump structure 117a) is integrally formed on the substrate of the mother board by, for example, thermoforming to form the mother board 110a having the first board body 112a with the cavity 115a and the contour feature (i.e., the bump structure 117a) and the first electrical contact 114a printed on the first board body 112a. Similarly, the second electrical contact 124a is printed on a substrate of a daughter board to form the daughter board 120a having the second board body 122a and the second electrical contact 124a printed on the second board body 122a. After that, the daughter board 120a is assembled with the mother board 110a, that is, the second board body 122a is inserted into the cavity 115a of the first board body 112a, so that the second electrical contact 124a is electrically connected to the first electrical contact 114a, and the daughter board 120a is positioned in the mother board 110a through the contour feature 117a. Afterwards, through a signal connection test, if the test is normal, it may be output.

In short, in a design of the electrical connection device 100a in this embodiment, the mother board 110a includes the contour feature 117a integrally formed with the first board body 112a, which may effectively reduce material usage and process steps. Furthermore, when the second board body 122a is inserted into the cavity 115a of the first board body 112a, the second electrical contact 124a may be electrically connected to the first electrical contact 114a, and the daughter board 120a may be positioned in the mother board through the contour feature 117a, which means that the positioning and line connection of the daughter board 120a and the mother board 110a may be completed at the same time. Therefore, in addition to saving costs and improving assembly efficiency, the electrical connection device 100a in this embodiment may also have better reliability.

It should be noted that in this embodiment, the shape, number, and arrangement of the contour feature 117a are not limited, which will be described in different embodiments below.

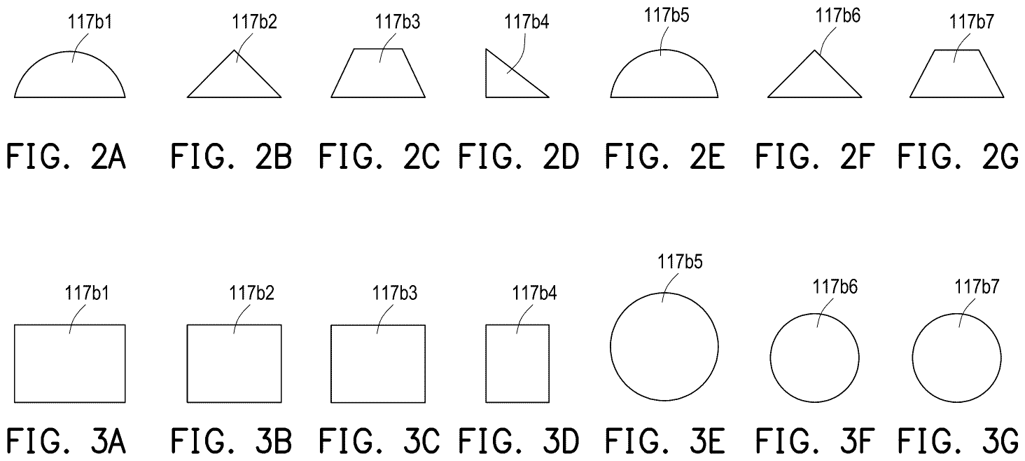

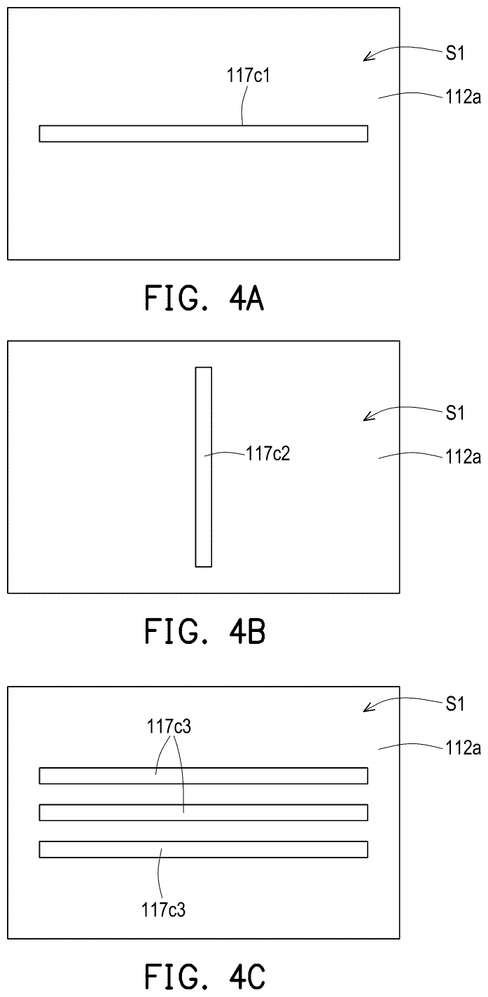

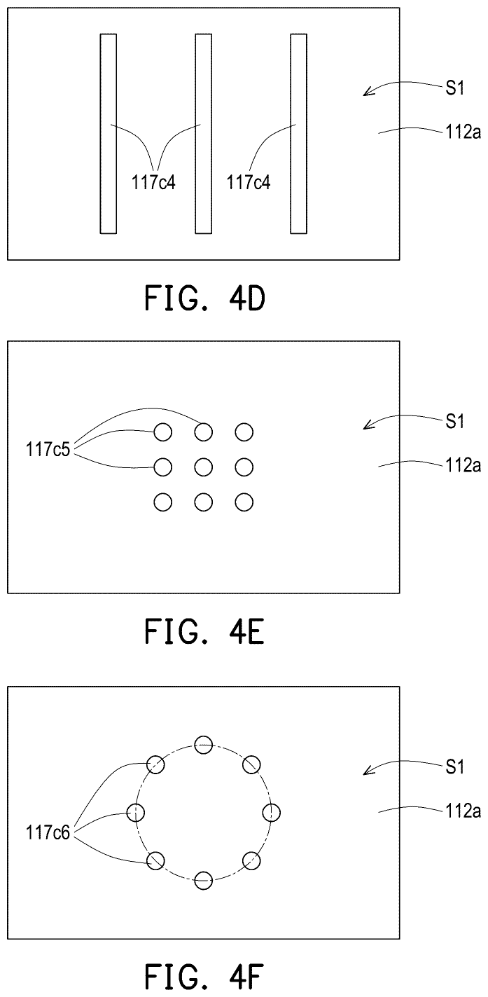

FIGS. 2A to 2G are side views of contour features of various shapes. FIGS. 3A to 3G are top views corresponding to the contour features in FIGS. 2A to 2G respectively. FIGS. 4A to 4F are schematic views of contour features with different numbers and arrangements.

Referring to both FIGS. 2A and 3A, in an embodiment, a shape of a contour feature 117b1 may be, for example, a semicircle when viewed from the side, and the shape of the contour feature 117b1 may be, for example, a rectangle when viewed from the top.

Referring to both FIGS. 2B and 3B, in an embodiment, a shape of a contour feature 117b2 may be, for example, a triangle when viewed from the side, and the shape of the contour feature 117b2 may be, for example, a rectangle when viewed from the top.

Referring to both FIGS. 2C and 3C, in an embodiment, a shape of a contour feature 117b3 may be, for example, a trapezoid when viewed from the side, and the shape of the contour feature 117b3 may be, for example, a rectangle when viewed from the top.

Referring to both FIGS. 2D and 3D, in an embodiment, a shape of a contour feature 117b4 may be, for example, a right triangle when viewed from the side, and the shape of the contour feature 117b4 may be, for example, a rectangle when viewed from the top.

Referring to both FIGS. 2E and 3E, in an embodiment, a shape of a contour feature 117b5 may be, for example, a semicircle when viewed from the side, and the shape of the contour feature 117b5 may be, for example, a circle when viewed from the top.

Referring to both FIGS. 2F and 3F, in an embodiment, a shape of a contour feature 117b6 may be, for example, a triangle when viewed from the side, and the shape of the contour feature 117b6 may be, for example, a circle when viewed from the top.

Referring to both FIGS. 2G and 3G, in an embodiment, a shape of a contour feature 117b7 may be, for example, a trapezoid when viewed from the side, and the shape of the contour feature 117b7 may be, for example, a circle when viewed from the top.

Next, referring to FIG. 4A, in an embodiment, there is one contour feature 117c1, which is rectangular in shape and arranged horizontally.

Referring to FIG. 4B, in an embodiment, there is one contour feature 117c2, which is rectangular in shape and arranged vertically.

Referring to FIG. 4C, in an embodiment, there are three contour features 117c3, which are rectangular in shape and arranged at horizontal intervals.

Referring to FIG. 4D, in an embodiment, there are three contour features 117c4, which are rectangular in shape and arranged at vertical intervals.

Referring to FIG. 4E, in an embodiment, there are nine contour features 117c5, which are circular in shape and arranged in a matrix.

Referring to FIG. 4F, in an embodiment, there are eight contour features 117c6, which are circular in shape and arranged in a circle.

Other embodiments are provided below for description. It is noted that some of the reference numerals and descriptions of the above embodiment will apply to the following embodiments. The same reference numerals will represent the same or similar components and the descriptions of the same technical contents will be omitted. Reference may be made to the above embodiment for the omitted descriptions, which will not be repeated in the following embodiments.

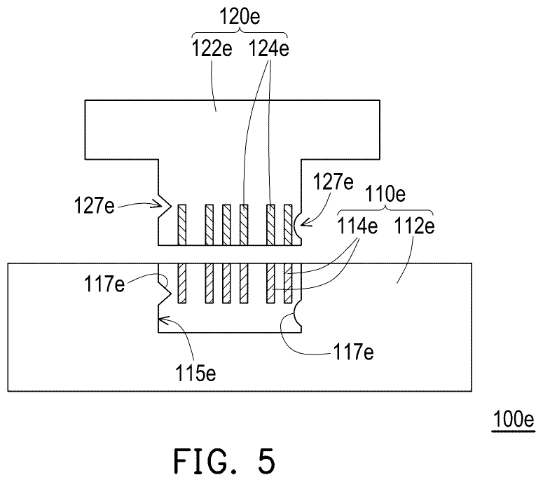

FIG. 5 is a schematic cross-sectional view of an electrical connection device according to another embodiment of the disclosure. Referring to both FIGS. 1B and 5, an electrical connection device 100e in this embodiment is similar to the above electrical connection device 100a. However, a main difference between the two is that in this embodiment, the at least one contour feature includes at least one first contour feature and at least one second contour feature. A mother board 110e includes the at least one first contour feature (two first contour features 117e are schematically shown), and a daughter board 120e includes the at least one second contour feature (two second contour features 127e are schematically shown). One of the first contour feature 117e and the second contour feature 127e is a bump structure, and the other one of the first contour feature 117e and the second contour feature 127e is a pit structure.

Here, the first contour feature 117e is, for example, a bump structure, and the second contour feature 127e is, for example, a pit structure. However, the disclosure is not limited thereto. In an embodiment, the two first contour features 117e may have the same or different shapes, and the disclosure is not limited thereto here. In an embodiment, the two second contour features 127e may have the same or different shapes, and the disclosure is not limited thereto here. As long as the two corresponding first contour feature 117e and second contour feature 127e may match each other in shape, they all fall within the scope of the disclosure. When the second board body 122e is inserted into a cavity 115e of a first board body 112e, a second electrical contact 124e is electrically connected to a first electrical contact 114e, and the daughter board 120e is positioned in the mother board 110e through matching of the first contour feature 117e and the second contour feature 127e, which means that the positioning and line connection of the daughter board 120e and the mother board 110e may be completed at the same time. That is to say, through the first contour features 117e and the second contour features 127e on the mother board 110e and the daughter board 120e having corresponding concave and convex structures, the daughter board 120e may be easily aligned with the mother board 110e, which may improve alignment accuracy, and is also suitable for rapid repeated plugging and unplugging operations.

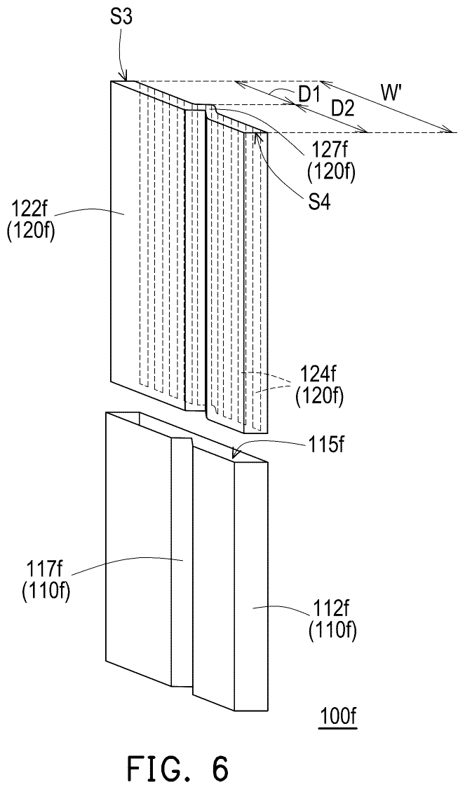

FIG. 6 is a schematic exploded perspective view of an electrical connection device according to another embodiment of the disclosure. Referring to both FIGS. 1A and 6, an electrical connection device 100f in this embodiment is similar to the above-mentioned electrical connection device 100a. However, a main difference between the two is that in this embodiment, the at least one contour feature includes the at least one first contour feature and the at least one second contour feature. The mother board 110f includes the at least one first contour feature (a first contour feature 117f is schematically shown), and a daughter board 120f includes the at least a second contour feature (a second contour feature 127f is schematically shown). The first contour feature 117f is a strip-shaped grooves, and the second contour feature 127f is a bending structure. Here, an extension direction of the strip-shaped groove 117f is parallel to an insertion direction of the daughter board 120f. Therefore, when a second board body 122f is inserted into a cavity 115f of a first board body 112f, the bending structure 127f may be disposed corresponding to the strip-shaped groove 117f.

In this embodiment, the daughter board 120f may be, for example, a flexible printed circuit board (FPC), a flexible flat cable (FFC), or a monolithic film. A thickness of the daughter board 120f may be, for example, less than 2 mm, and stiffness thereof is less than 20 g·cm. Since the daughter board 120f in this embodiment has the bending structure 127f integrally formed with the second board body 122f, the stiffness may be enhanced, and the daughter board 120f may be prevented from being deformed when inserted into the mother board 110f. Furthermore, the mother board 110f has the strip-shaped groove 117f integrally formed with the first board body 112f, and the strip-shaped groove 117f is disposed corresponding to the bending structure 127f, which may effectively increase alignment accuracy between the daughter board 120f and the mother board 110f.

Furthermore, the daughter board 120f has a first side S3 and a second side S4 opposite to each other. Preferably, a distance D1 from the bending structure 127f to the first side S3 is 51% to 70% of the width W′ of the daughter board 120f. A distance D2 from the bending structure 127f to the second side S4 is 30% to 49% of the width W′ of the daughter board 120f. That is to say, the bending structure 127f is not located in a center of the daughter board 120f, but has an asymmetric design with the first side S3 and the second side S4. Preferably, when the daughter board 120f is inserted into the mother board 110f, a contact area between a second electrical contact 124f and the first electrical contact (not shown) should be at least 50% greater than a complete contact area to ensure that an electrical signal is correctly transmitted. That is to say, when the daughter board 120f is inserted into the mother board 110f, an overlapping region/contact area of the second electrical contact 124f of the daughter board 120f and the first electrical contact of the mother board 110f is required to overlap by at least half of the width to ensure quality of electrical conduction. In addition, the bending structure 127f may be formed by one single straight strip or multiple strips, and the disclosure is not limited thereto.

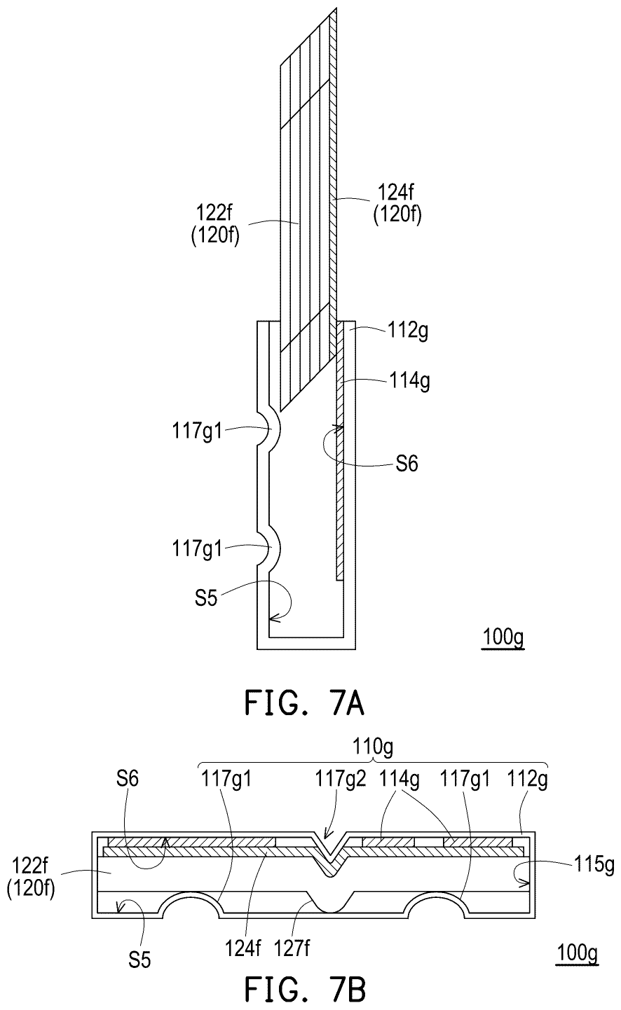

FIG. 7A is a schematic cross-sectional view of an electrical connection device according to another embodiment of the disclosure. FIG. 7B is a schematic top perspective view of the electrical connection device in FIG. 7A. referring to FIGS. 6, 7A, and 7B together, an electrical connection device 100g in this embodiment is similar to the above-mentioned electrical connection device 100f. However, a main difference between the two is that in this embodiment, a mother board 110g includes two first contour features 117g1 and a first contour feature 117g2. The first contour feature 117g1 is the bump structure 117g1, and the first contour feature 117g2 is the strip-shaped groove 117g2. A cavity 115g has a first inner side surface S5 and a second inner side surface S6 opposite to each other. The bump structure 117g1 is located on the first inner side surface S5, and the strip-shaped groove 117g2 is concave from the second inner side surface S6 and extends toward a direction of the first inner side surface S5. When the second board body 122f is inserted into the cavity 115g of a first board body 112g, the bending structure 127f of the second board body 122f is disposed corresponding to the strip-shaped 117g2, and the daughter board 120f is positioned in the mother board 110g through matching of the bump structure 117g1, the strip-shaped groove 117g2, and the bending structure 127f.

When the cavity 115g corresponding to the thin daughter board 120f is formed, it is easy to have uneven thicknesses or deformation in different regions due to a large aspect ratio. Therefore, when the mother board 110g is formed, the strip-shaped groove 117g2 in the insertion direction with the daughter board 120f and the bump structure 117g1 on an opposite side of the strip-shaped groove 117g2 are formed, which may effectively provide firm pressure to stabilize a first electrical contact 114g and the second electrical contact 124f.

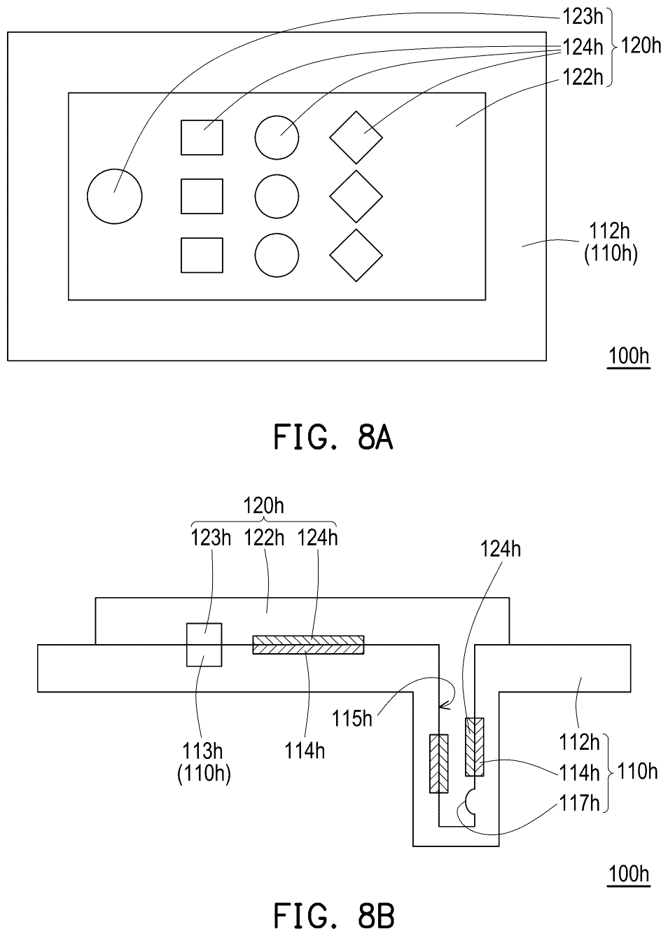

FIG. 8A8A is a schematic top perspective view of an electrical connection device according to another embodiment of the disclosure. FIG. 8B is a schematic cross-sectional view of the electrical connection device in FIG. 8A. Referring to FIGS. 1B, 8A, and 8B together, an electrical connection device 100h in this embodiment is similar to the above-mentioned electrical connection device 100a. However, a main difference between the two is that in this embodiment, a mother board 110h further includes at least one first magnetic member (a first magnetic member 113h is schematically shown), and a daughter board 120h further includes at least one second magnetic member (a second magnetic member 123h is schematically shown). A magnetic pole of one of the first magnetic member 113h and the second magnetic member 123h is an S pole, and a magnetic pole of the other one of the first magnetic member 113h and the second magnetic member 123h is an N pole. Here, the magnetic pole of the first magnetic member 113h is, for example, the S pole, and the magnetic pole of the second magnetic member 123h is, for example, the N pole. However, the disclosure is not limited thereto.

When a second board body 122h is inserted into a cavity 115h of a first board body 112h, the second magnetic member 123h is magnetically attracted to the first magnetic member 113h, a second electrical contact 124h is electrically connected to a first electrical contact 114h, and the daughter board 120h is positioned in the mother board 110h through a contour feature 117h (e.g., the bump structure), which means that the positioning and line connection of the daughter board 120h and the mother board 110h may be completed at the same time. In other words, through a set of magnetic mechanism components, in addition to increasing a self-alignment function during assembly, the electrical connection device 100h with the single cavity 115h may also improve adhesion of the electrical connection device 100h and improve a reliability test and seismic resistant performance of mobile device products.

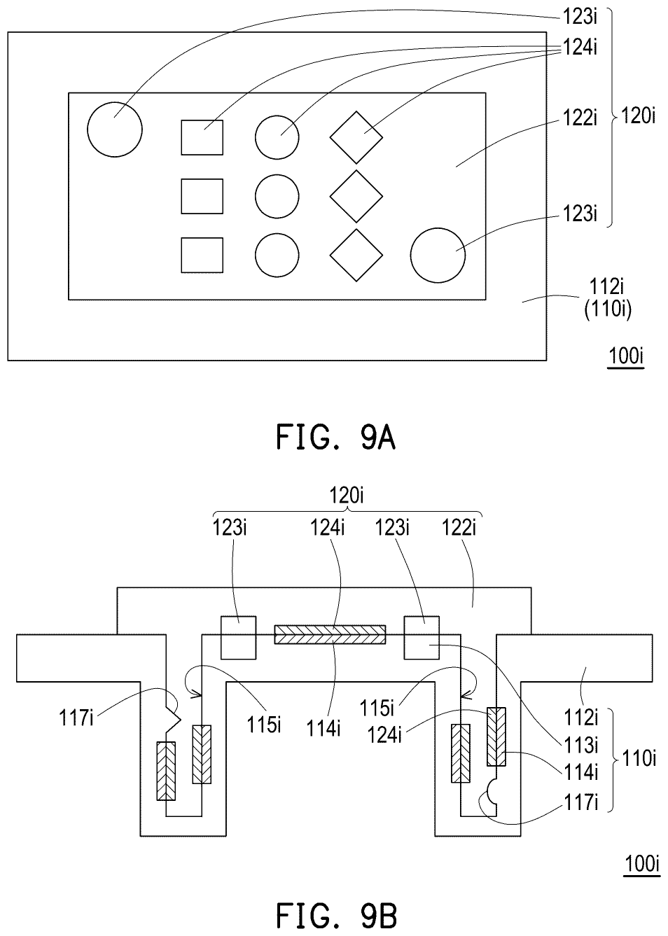

FIG. 9 Ais a schematic top perspective view of an electrical connection device according to another embodiment of the disclosure. FIG. 9B is a schematic cross-sectional view of the electrical connection device in FIG. 9A. Referring to FIGS. 1B, 9A, and 9B together, an electrical connection device 100i in this embodiment is similar to the above-mentioned electrical connection device 100a. However, a main difference between the two is that in this embodiment, a mother board 110i has two cavities 115i, and each of the cavities 115i has a contour feature 117i (e.g., the bump structure) integrally formed with a first board body 112i. The mother board 110i further includes the at least one first magnetic member (two first magnetic members 113i are schematically shown), and a daughter board 120i further includes the at least one second magnetic member (two second magnetic members 123i are schematically shown). A magnetic pole of one of the first magnetic member 113i and the second magnetic member 123i is the S pole, and a magnetic pole of the other one of the first magnetic member 113i and the second magnetic member 123i is the N pole. Here, the magnetic poles of the two first magnetic members 113i are, for example, the S pole and the N pole respectively, and the magnetic poles of the two second magnetic members 123i corresponding to the two first magnetic members 113i are, for example, the N pole and the S pole, respectively. However, the disclosure is not limited thereto.

When a second board body 122i is inserted into the two cavities 115i of the first board body 112i, the second magnetic member 123i is magnetically attracted to the first magnetic member 113i, a second electrical contact 124i is electrically connected to a first electrical contact 114i, and the daughter board 120i is positioned in the mother board 110i through the contour feature 117i (e.g., the bump structure), which means that the positioning and line connection of the daughter board 120i and the mother board 110i may be completed at the same time. Compared to the existing technology that requires a lot of manpower for operations such as wiring and welding, a design of the electrical connection device 100i in this embodiment may have functions of both assembly fool-proofing and enhanced adsorption, which may effectively save manufacturing costs and improve efficiency. In addition, the magnetic components are disposed in the integrally formed mother board 110i and the device that requires multiple plugging and unplugging, which may not only strengthen a structural design of the electrical connection device 100i, but also improve reliability of quality of component assembly.

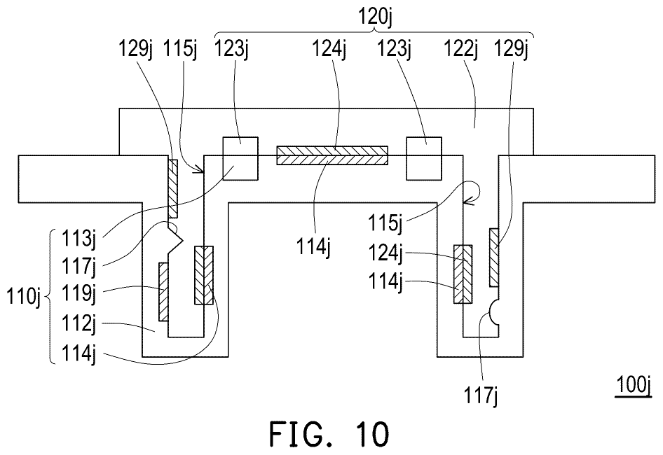

FIG. 10 is a schematic cross-sectional view of an electrical connection device according to another embodiment of the disclosure. Referring to both FIGS. 9B and 10, an electrical connection device 100j in this embodiment is similar to the above-mentioned electrical connection device 100i. However, a main difference between the two is that in this embodiment, a mother board 110j further includes at least one first thermal contact (one first thermal contact 119j is schematically shown), and a daughter board 120j further includes at least one second thermal contact (two second thermal contacts 129j are schematically shown). In an embodiment, a material of the first thermal contact 119j and a material of the second thermal contact 129j may be the same as or different from a material of a first electrical contact 114j and a material of a second electrical contact 124j. However, the disclosure is not limited thereto.

When a second board body 122j is inserted into two cavities 115j of a first board body 112j, a second magnetic member 123j is magnetically attracted to a first magnetic member 113j, the second electrical contact 124j is electrically connected to the first electrical contact 114j, and the daughter board 120j is positioned in the mother board 110j through a contour feature 117j (e.g., the bump structure), while the second thermal contact 123j and the first thermal contact 113j are disposed in an misalignment manner. That is to say, in addition to the electrical contact connection, the electrical connection device 100j in this embodiment also has the thermal contacts, which may be used as a radiator or a heater.

It should be noted that at least one of the daughter board and the mother board includes the at least one contour feature, the at least one contour feature is integrally formed with at least one of the first board body and the second board body, and the heterosexual magnetic members are disposed on the daughter board and the mother board. The above structural settings may exist alone or be used in combination according to use requirements, and the disclosure is not limited thereto here.

Based on the above, in the design of the electrical connection device in the disclosure, at least one of the daughter board and the mother board includes the at least one contour feature, and the at least one contour feature is integrally formed with at least one of the first board body and the second board body, which may reduce the material usage and the process steps. Therefore, when the second board body is inserted into the at least one cavity of the first board body, the second electrical contact is electrically connected to the first electrical contact, and the daughter board is positioned in the mother board through the at least one contour feature, which means that the positioning and line connection of the daughter board and the mother board may be completed at the same time, so that the electrical connection device in the disclosure may not only save costs and improve assembly efficiency, but also have better reliability.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. An electrical connection device, comprising:
a mother board comprising a first board body with at least one cavity and a first electrical contact printed on the first board body; and
a daughter board comprising a second board body and a second electrical contact printed on the second board body, wherein at least one of the daughter board and the mother board comprises at least one contour feature, the at least one contour feature is integrally formed with at least one of the first board body and the second board body, and when the second board body is inserted into the at least one cavity of the first board body, the second electrical contact is electrically connected to the first electrical contact, and the daughter board is positioned in the mother board through the at least one contour feature.

2. The electrical connection device according to claim 1, wherein the mother board comprises the at least one contour feature, the at least one contour feature comprises a bump structure, the at least one cavity has an upper surface and a bottom surface opposite to each other and a first inner side surface and a second inner side surface connected to the upper surface and the bottom surface and opposite to each other, the bump structure is located on the first inner side surface, and the first electrical contact extends from the upper surface and is disposed on the second inner side surface.

3. The electrical connection device according to claim 2, wherein a protruding height of the bump structure relative to the first inner side surface is d, a width of the at least one cavity is W, and then 0<d<(W/2).

4. The electrical connection device according to claim 3, wherein a thickness of the first electrical contact and a thickness of the second electrical contact range from 0.002 mm to 0.5 mm respectively.

5. The electrical connection device according to claim 2, wherein an orthographic projection area of the bump structure on the second inner side surface is at least 20% greater than a contact area between the second electrical contact and the first electrical contact.

6. The electrical connection device according to claim 2, wherein a maximum stress value applied by the bump structure on the daughter board is less than a material yield strength of the mother board.

7. The electrical connection device according to claim 2, wherein average contact force between the second electrical contact and the first electrical contact is greater than 100 gram force.

8. The electrical connection device according to claim 1, wherein a shape of the bump structure comprises a semicircle, a triangle, or a trapezoid when viewed from a side.

9. The electrical connection device according to claim 1, wherein a shape of the bump structure comprises a rectangle or a circle when viewed from a top.

10. The electrical connection device according to claim 1, wherein the at least one contour feature comprises a plurality of contour features, and the contour features are arranged at intervals, in an array, or in a circular circle.

11. The electrical connection device according to claim 1, wherein the at least one contour feature comprises at least one first contour feature and at least one second contour feature, the mother board comprises the at least one first contour feature, the daughter board comprises the at least one second contour feature, one of the at least one first contour feature and the at least one second contour feature is at least one bump structure, and the other one of the at least one first contour feature and the at least one second contour feature is at least one pit structure.

12. The electrical connection device according to claim 1, wherein the at least one contour feature comprises at least one first contour feature and at least one second contour feature, the mother board comprises the at least one first contour feature, the daughter board comprises the at least one second contour feature, the at least one first contour feature comprises a strip-shaped groove, the at least one second contour feature comprises a bending structure, and when the second board body is inserted into the at least one cavity of the first board body, the bending structure is disposed corresponding to the strip-shaped groove.

13. The electrical connection device according to claim 12, wherein the daughter board has a first side and a second side opposite to each other, a distance from the bending structure to the first side is 51% to 70% of a width of the daughter board, and a distance from the bending structure to the second side is 30% to 49% of the width of the daughter board.

14. The electrical connection device according to claim 1, wherein the at least one contour feature comprises at least one first contour feature and at least one second contour feature, the mother board comprises the at least one first contour feature, the daughter board comprises the at least one second contour feature, the at least one first contour feature comprises at least one bump structure and a strip-shaped groove, the at least one cavity has a first inner side surface and a second inner side surface opposite to each other, the bump structure is located on the first inner side surface, the strip-shaped groove is concave from the second inner side surface and extends toward a direction of the first inner side surface, the at least one second contour feature comprises a bending structure, and when the second board body is inserted into the at least one cavity of the first board body, the bending structure is disposed corresponding to the strip-shaped groove, and the daughter board is positioned in the mother board through the at least one bump structure.

15. The electrical connection device according to claim 1, wherein the mother board further comprises at least one first magnetic member, the daughter board further comprises at least one second magnetic member, and when the second board body is inserted into the at least one cavity of the first board body, the at least one second magnetic member is magnetically attracted to the at least one first magnetic member.

16. The electrical connection device according to claim 15, wherein a magnetic pole of one of the at least one first magnetic member and the at least one second magnetic member is an S pole, and a magnetic pole of the other one of the at least one first magnetic member and the at least one second magnetic member is an N pole.

17. The electrical connection device according to claim 1, wherein the mother board further comprises at least one first thermal contact, the daughter board further comprises at least one second thermal contact, and when the second board body is inserted into the at least one cavity of the first board body, the at least one second thermal contact and the at least one first thermal contact are disposed in a misalignment manner.
